(19) United States
(12) Patent Application Publication
(10) Pub. No.: US 2026/0105234 A1
(43) Pub. Date: Apr. 16, 2026

(54) TEST METHOD FOR INTEGRATED CIRCUIT AND INTEGRATED CIRCUIT USING THE SAME

(71) Applicant: FOCALTECH SYSTEMS CO., LTD., Zhubei City (TW)

(72) Inventor: FANG-YI SU, Zhubei City (TW)

(21) Appl. No.: 19/335,772

(22) Filed: Sep. 22, 2025

(30) Foreign Application Priority Data
Oct. 14, 2024 (TW) 113139040

(51) Int. Cl. G06F 30/367; G06F 30/31

(52) U.S. Cl. CPC G06F 30/367; G06F 30/31

(57) ABSTRACT

A test method for an integrated circuit and an integrated circuit using the same are provided in the embodiments of the present invention. In the analog circuit block, a check bit generation circuit is set up to generate a check bit from multiple test points. An automatic placement and routing block comprises a test pattern generation circuit that generates test signals from control signal output terminals. The automatic placement and routing block generates a verification bit based on these test signals and compares it with the check bit. If the verification bit doesn't match the check bit, the integrated circuit may be deemed abnormal. This method provides an effective integrated testing of different blocks, improves the efficiency and accuracy of integrated circuit inspection.

### CROSS-REFERENCE TO RELATED APPLICATIONS

This application claims priority of No. 113139040 filed in Taiwan R.O.C. on Oct. 14, 2024 under 35 USC 119, the entire content of which is hereby incorporated by reference.

### BACKGROUND OF THE INVENTION

### Field of the Invention

The present invention relates to the technology of integrated circuit testing, and more particularly, to a test method for integrated circuit and an integrated circuit using the same.

### Description of the Related Art

Conventional integrated circuit (IC) testing techniques have primarily focused on the testing of digital circuits, especially within the Automatic Placement and Routing (APR) region. These testing methods mainly rely on Electronic Design Automation (EDA) tools to insert scan chains within the APR region. A scan chain includes a series of scan D flip-flops that are connected in sequence during test mode to form a long shift register. In this way, test vectors can be serially shifted into the circuit and then applied in parallel to the logic under test. The test results are subsequently captured by these flip-flops and serially shifted out through the scan chain for analysis. This approach effectively detects defects in the APR region, particularly stuck-at faults.

FIG. 1 illustrates the test setup of an integrated circuit according to the prior art. In the figure, region 101 represents the APR portion, which includes scan chain structures inserted by EDA tools. This structure enables comprehensive testing of most digital circuit areas, significantly improving fault coverage and testing efficiency.

However, this conventional scan testing method has a significant limitation in that it cannot effectively test the analog circuit (Analog IP) portions, especially the control signals of the analog circuit 102. As shown in FIG. 1, although the control signals for the analog circuit 102 originate from the APR (digital area), these signals are not included in the scan chain's test coverage. This means that even if the scan test for the digital portion is successfully performed, abnormalities in the control signals of the analog circuit 102 may still go undetected. This incomplete test coverage could lead to critical faults being overlooked, particularly issues at the analog-digital interface. For example, if the control signals cannot be properly transmitted to the analog circuit 102 due to manufacturing defects or other causes, the functionality of the entire integrated circuit may be severely affected. However, such faults cannot be identified using conventional scan testing methods.

### BRIEF SUMMARY OF THE INVENTION

An objective of the present invention is to provide a testing method for integrated circuits and the integrated circuit using the same, which allows for the testing of analog circuit blocks in a mixed-signal integrated circuit. Additionally, the intermediate control interface blocks can also be tested. As a result, test coverage can be easily increased during mass production testing, thereby achieving the goal of low-cost testing.

In view of this, the embodiment of the present invention provides an integrated circuit. The integrated circuit comprising an analog circuit block, an automatic placement and routing (APR) block, and a control interface block. The analog circuit block operates with a first operating voltage and includes a plurality of control signal receiving terminals. The APR block operates with a second operating voltage and includes a plurality of control signal output terminals. The control interface block is coupled between the control signal output terminals of the APR block and the control signal receiving terminals of the analog circuit block. The analog circuit block includes a check-bit generation circuit, which includes a plurality of input terminals and one output terminal. The input terminals of the check-bit generation circuit are respectively coupled to a plurality of test points in the analog circuit block. Each of these test points is controlled by at least one of the control signal output terminals of the APR block, and the check-bit generation circuit is configured to generate a check bit via its output terminal. The APR block includes a test pattern generation circuit and a verification circuit. The test pattern generation circuit includes a plurality of output terminals respectively coupled to the control signal output terminals of the APR block to generate corresponding test signals and a verification bit during an analog test mode. The verification circuit includes a first input terminal, a second input terminal, and an output terminal. The first input terminal of the verification circuit is coupled to the output terminal of the check-bit generation circuit, and the second input terminal receives the verification bit.

The embodiment of the invention further provides a method for testing an integrated circuit. The testing method for the integrated circuit comprises: providing an analog circuit block and an APR block in the integrated circuit; configuring a check bit generation circuit in the analog circuit block, wherein a plurality of test points in the analog circuit block is served as inputs of the check bit generation circuit for outputting a check bit; configuring a test pattern generation circuit in the automatic placement and routing block for outputting a plurality of test signals via a plurality of control signal output terminals of the automatic placement and routing block; generating a verification bit based on the test signals; and verifying whether the check bit matches the verification bit; determining a faulty of the integrated circuit when the check bit does not match the verification bit.

A preferred embodiment of the present invention provides an innovative integrated circuit design featuring a multifunctional testing mechanism, which includes a check-bit generation circuit, a test pattern generation circuit, and a verification circuit. These components work in coordination to enable comprehensive testing of the circuit in both analog and digital modes. By employing a set of scan D-type flip-flops, the preferred embodiment further enhances digital testing capabilities while maintaining flexibility for analog testing. Notably, in this preferred embodiment, since the automatic placement and routing (APR) block is implemented by using a hardware description language (HDL), the design intentionally couples the output of the test pattern generation circuit to the scan D-type flip-flop set. This design approach not only improves the comprehensiveness and accuracy of testing but also significantly enhances the reliability and manufacturing efficiency of the circuit. It offers a powerful and flexible solution for the design and testing of modern mixed-signal integrated circuits.

The above-mentioned and other objects, features and advantages of the present invention will become more apparent from the following detailed descriptions of preferred embodiments taken in conjunction with the accompanying drawings.

### BRIEF DESCRIPTION OF THE SEVERAL VIEWS OF THE DRAWINGS

The accompanying drawings are provided to enable those skilled in the relevant technical field to further understand the present invention and are incorporated into and form a part of the present specification. The drawings illustrate exemplary embodiments of the invention and, together with the description, serve to explain the principles of the invention.

FIG. 1 illustrates a schematic diagram depicting the test setup of an integrated circuit according to the prior art.

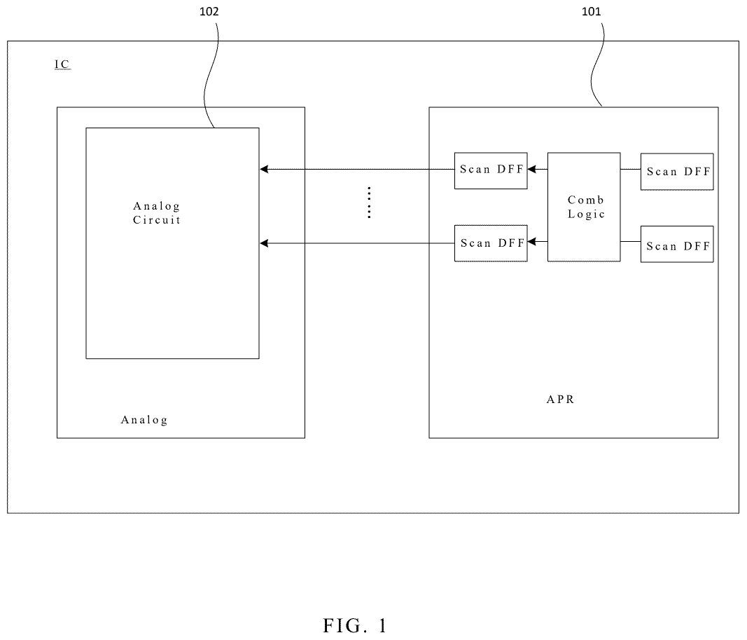

FIG. 2 illustrates a circuit block diagram depicting an integrated circuit according to a preferred embodiment of the present invention.

FIGS. 3A to 3D illustrate schematic diagrams depicting the testing of an integrated circuit according to a preferred embodiment of the present invention.

FIG. 4 illustrates a circuit diagram depicting a test pattern generation circuit (PatG) of an integrated circuit according to a preferred embodiment of the present invention.

FIG. 5 illustrates a flowchart depicting the testing method for an integrated circuit according to a preferred embodiment of the present invention.

### DETAILED DESCRIPTION OF THE INVENTION

The exemplary embodiments of the present invention, which are illustrated in the accompanying drawings, are provided. Wherever possible, the same reference numbers are used in the drawings and description to refer to the same or like parts. In addition, the practice of the exemplary embodiment is only one of the implementations of the design concept of the present invention, and thus, the present invention is not limit thereto.

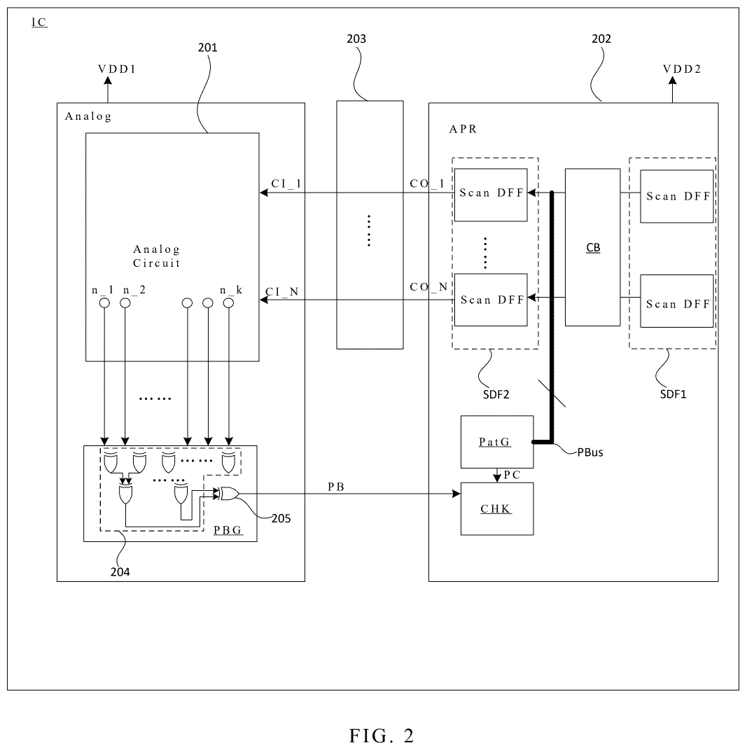

FIG. 2 illustrates a circuit block diagram depicting an integrated circuit according to a preferred embodiment of the present invention. As shown in FIG. 2, the integrated circuit includes an analog circuit block 201, an automatic placement and routing (APR) block 202, and a control interface block 203. The analog circuit block 201 operates at a first supply voltage VDD1. The APR block 202 operates at a second supply voltage VDD2. In this embodiment, the first supply voltage VDD1 is greater than the second supply voltage VDD2. This integrated circuit belongs to the category of mixed-signal ICs, which combine analog and digital circuits. Since the digital portion (APR block 202) is used to control the analog circuit block 201, a control interface block 203 is necessary between the APR block 202 and analog circuit block 201.

The analog circuit block 201 includes a plurality of control signal input terminals CI_1 to CI_N. The APR block 202 includes a plurality of control signal output terminals CO_1 to CO_N. The control interface block 203 is coupled between the control signal output terminals CO_1 to CO_N of the APR block 202 and the control signal input terminals CI_1 to CI_N of the analog circuit block 201. Generally, each control signal output from the APR block 202 requires at least one level shifter. Accordingly, in this embodiment, the control interface block 203 includes multiple level shifters (not shown), although the number and type of level shifters are not limited.

The analog circuit block 201 further includes a check-bit generation circuit PBG. The input terminals of the check-bit generation circuit PBG are respectively coupled to a plurality of test points n_1 to n_k in the analog circuit block 201, each of test points n_1 to n_k in the analog circuit block 201 are controlled by at least one of the control signal output terminals CO_1 to CO_N of the APR block. The check-bit generation circuit PBG outputs a check bit PB based on the logic states at the test points. In this embodiment, the check-bit generation circuit PBG is implemented using combinational logic. Since the check-bit generation circuit PBG is located in the analog circuit block 201, the check-bit generation circuit PBG is implemented using a full custom design flow, which means that the circuit layout thereof is manually drawn. As such, all required test points can be manually and electrically connected to the inputs of the check-bit generation circuit PBG. The check bit PB output from the check-bit generation circuit PBG indicates whether an error has occurred.

Specifically, the combinational logic of the check-bit generation circuit PBG may include, for example, multi-stage XOR logic gates 204 and a check bit XOR logic gate 205. This arrangement of the multi-stage XOR logic gates 204 and the check bit XOR logic gate 205 allows different test signals to determine which control signal input terminal CI_1 to CI_N or output terminal CO_1 to CO_N may have encountered an error.

In this embodiment, the APR block 202 includes a combinational logic circuit CB, a first scan D flip-flop group SDF1, a second scan D flip-flop group SDF2, a test pattern generation circuit PatG, and a verification circuit CHK. Under normal operating conditions, the first scan D flip-flop group SDF1 and the second scan D flip-flop group SDF2 are served as conventional D flip-flops for buffering, temporary storage, and synchronization. However, during testing of the combinational logic circuit CB, the first scan D flip-flop group SDF1 and the second scan D flip-flop group SDF2 are configured in digital test mode to operate as shift registers. Using an external EDA (Electronic Design Automation) tool, sequences of logic data are input to test every logic element in the combinational logic circuit CB. Due to the large test data volume, assistance from external EDA tools is required.

In this embodiment, the test pattern generation circuit PatG includes a plurality of output terminals, represented as a bus PBus. The output terminals PBus of the test pattern generation circuit PatG are coupled to the input terminals of the second scan D flip-flop group SDF2. Alternatively, the output terminals PBus of the test pattern generation circuit PatG may be coupled to the output terminals of the second scan D flip-flop group SDF2. Since all circuits in the APR block 202 are implemented using a hardware description language (HDL) and generated via a cell-based design flow, connecting the output terminals PBus of the test pattern generation circuit PatG outputs to the input terminals of SDF2 ensures that the circuit between SDF2 and the control interface block 203 is covered by the test. If the output terminals PBus of the test pattern generation circuit PatG are coupled to the output terminals of the second scan D flip-flop group SDF2, the automatically generated routing may not guarantee proper connection to the downstream circuits. As a result, any open circuit between the second scan D flip-flop group SDF2 and the control interface block 203 may be undetected, and it is also possible for the test results to appear normal on the faulty circuit. Therefore, in this embodiment, connecting the output terminals PBus of the test pattern generation circuit PatG to the input terminals of SDF2 is adopted to improve test coverage.

When the system enters analog test mode, the output terminals PBus of the test pattern generation circuit PatG generate a plurality of test signals and a verification bit PC. The first input terminal of the verification circuit CHK is coupled to the output terminal of the check-bit generation circuit PBG. The second input terminal of the verification circuit CHK receives the verification bit PC. The verification circuit CHK is used to compare the check bit PB with the verification bit PC and see whether they match each or not. If the check bit PB and the verification bit PC match, the result is deemed normal; if the check bit PB and the verification bit PC differ, the IC is considered abnormal. The verification circuit CHK may be implemented using an XOR logic gate, an XNOR logic gate, or other equivalent combinational logic.

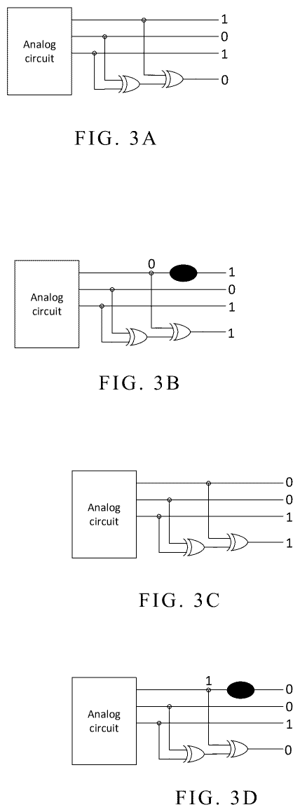

FIGS. 3A-3D illustrate schematic diagrams depicting the testing process for the integrated circuit according to a preferred embodiment of the present invention. Referring to FIGS. 3A and 3B, for example, if the output terminals PBus of the test pattern generation circuit PatG outputs [1 0 1], and the check-bit generation circuit PBG performs XOR logic to produce 0, this indicates that all three test points are functioning normally (FIG. 3A). Conversely, if the same input [1 0 1] results in a check bit of 1 (FIG. 3B), this indicates an error in at least one test point. Similarly, as shown in FIG. 3C, the output terminals PBus of the test pattern generation circuit PatG output of [0 0 1], resulting in a check bit of 1, it indicates a normal condition. However, if the same [0 0 1] input results in a check bit of 0 (FIG. 3D), this indicates a fault among the test points. In essence, any discrepancy in the expected result indicates that an internal circuit fault has occurred, and the integrated circuit should be classified as defective.

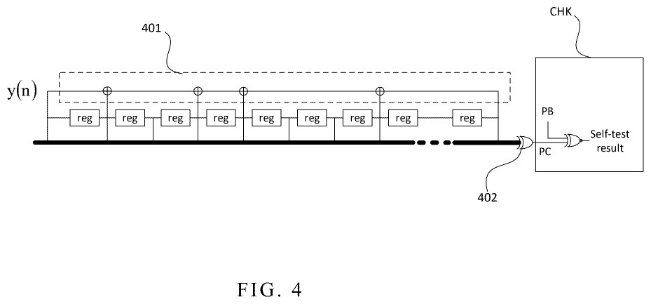

FIG. 4 illustrates a circuit diagram depicting the test pattern generation circuit PatG in an integrated circuit according to a preferred embodiment of the present invention. Referring to FIG. 4, in this embodiment, the test pattern generation circuit PatG is implemented by using a plurality of shift registers reg, a plurality of chained feedback XOR gates 401, and an XOR logic gate 402. Primarily, the shift registers are used to form a shift register chain and a polynomial function is utilized to determining the coupling relationship of the shift registers so that a pseudo-random sequence is generated. In this embodiment, the polynomial function is as follows:

$$y ( n ) = {x}^{1} + {x}^{3} + {x}^{4} + {x}^{7} + ... + {x}^{m}$$

As above polynomial function shown in this embodiment, the highest degree of the polynomial function is m, and therefore m shift registers are used. Since the polynomial function includes terms such as x¹, x³, x⁴, x⁷, etc., this means that the output terminals of the first, third, fourth, and seventh shift registers, respectively, are involved in XOR operations, and the result is fed back to the input terminal of the first shift register. Additionally, each output terminal of the shift registers serves as one of the multiple output terminals (PBus) of the test pattern generation circuit PatG. This specific feedback configuration produces a sequence that appears random but is in fact deterministic. When properly designed, it can generate a long non-repeating sequence. The test pattern generation circuit PatG in this preferred embodiment can thus produce a large number of distinct test patterns, widening the coverage range of possible fault conditions. Moreover, the hardware implementation is simple and compact, making it adapted for integration in an integrated circuit. It also allows for the rapid generation of test sequences, improving overall testing efficiency. Additionally, the aforementioned XOR logic gate 402 is primarily used to perform XOR operations on the generated test sequence to produce the check bit PC.

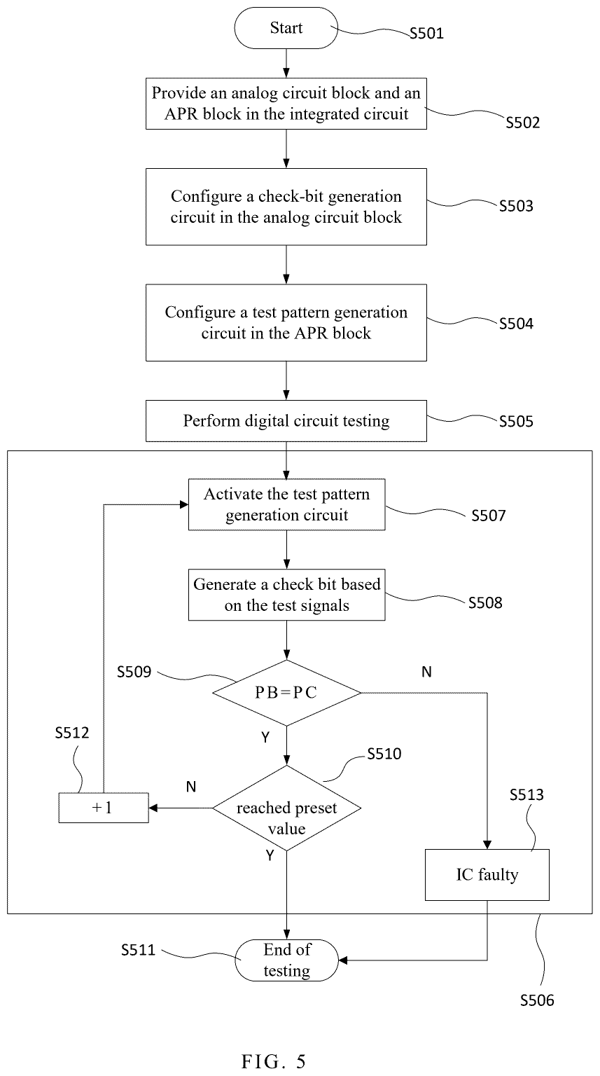

Based on the above-described embodiment, a testing method for an integrated circuit can be summarized. FIG. 5 illustrates a flowchart depicting a testing method for an integrated circuit according to a preferred embodiment of the present invention. Refer to FIG. 5. The testing method includes the following steps:
Step S501: Start.
Step S502: Provide an analog circuit block and an automatic placement and routing (APR) block in the integrated circuit.
Step S503: Configure a check-bit generation circuit in the analog circuit block. The circuit takes a plurality of test points from the analog circuit block as inputs and outputs a check bit PB.
Step S504: Configure a test pattern generation circuit in the APR block. The circuit outputs multiple test signals through the control signal output terminals of the APR block. As described in the aforementioned embodiment, the preferred implementation includes the outputs of the test pattern generation circuit coupled to the second scan D-type flip-flop group SDF2 in order to improve test coverage. However, the present invention is not limited thereto.
Step S505: Perform digital circuit testing. As described in the above embodiment, an electronic design automation (EDA) tool is adapted to input a sequence of logic data externally such that each logic unit of the combinational logic circuit CB can be tested.
Step S506: Perform analog circuit testing, which includes:
Step S507: Activate the test pattern generation circuit to output the aforementioned multiple test signals. As described in the embodiment, the test patterns are generated continuously and pseudo-randomly through polynomial operations.
Step S508: Generate a check bit based on the test signals. In the embodiment, the pseudo-random test patterns are processed through XOR logic to produce the check bit PC.
Step S509: Determine whether the check bit and the previously generated check bit PB are equal. If yes, proceed to Step S510. If not, proceed to Step S513.
Step S510: Determine whether the number of test iterations has reached a preset value. If the limit is reached, proceed to Step S511. If not, continue to Step S512.
Step S511: End of testing.
Step S512: Increment the test count by one. Then return to Step S507 to continue testing.
Step S513: Determine a faulty of the integrated circuit. Proceed to Step S511.

In summary, the preferred embodiment of the present invention provides an innovative integrated circuit design featuring a multifunctional testing mechanism, which includes a check-bit generation circuit, a test pattern generation circuit, and a verification circuit. These components operate in coordination to enable comprehensive testing of the circuit in both analog and digital modes. By utilizing a set of scan D-type flip-flops, the preferred embodiment further enhances digital testing capabilities while maintaining flexibility for analog testing. Notably, in the preferred embodiment of the present invention, since the automatic placement and routing (APR) block is implemented by using a hardware description language (HDL), the output terminals of the test pattern generation circuit are deliberately coupled to the scan D-type flip-flop set during the design phase. This design approach not only improves the comprehensiveness and accuracy of the testing process, but also significantly enhances the reliability and manufacturing efficiency of the circuit, thereby providing a robust and flexible solution for the design and testing of modern mixed-signal integrated circuits.

While the present invention has been described by way of examples and in terms of preferred embodiments, it is to be understood that the present invention is not limited thereto. To the contrary, it is intended to cover various modifications. Therefore, the scope of the appended claims should be accorded the broadest interpretation so as to encompass all such modifications.

What is claimed is:

1. An integrated circuit, comprising:
an analog circuit block, operating with a first operating voltage, comprising a plurality of control signal input terminals;
an automatic placement and routing block, operating with a second operating voltage, comprising a plurality of control signal output terminals; and
a control interface block, coupled between the plurality of control signal output terminals of the automatic placement and routing block and the plurality of control signal input terminals of the analog circuit block;
wherein the analog circuit block comprises:
a check bit generation circuit, comprising a plurality of input terminals and an output terminal, wherein the plurality of input terminals of the check bit generation circuit are respectively coupled to a plurality of test points in the analog circuit block, wherein each of the test points is controlled by at least one of the control signal output terminals of the automatic placement and routing block, and the check bit generation circuit is configured to generate a check bit outputted to the output terminal of the check bit generation circuit;
wherein the automatic placement and routing block comprises:
a test pattern generation circuit, comprising a plurality of output terminals, wherein the plurality of output terminals of the test pattern generation circuit are respectively coupled to the plurality of control signal output terminals of the automatic placement and routing block to generate a corresponding plurality of test signals and a verification bit during an analog test mode; and
a verification circuit, comprising a first input terminal, a second input terminal, and an output terminal, wherein the first input terminal of the verification circuit is coupled to the output terminal of the check bit generation circuit, and the second input terminal receives the verification bit.

2. The integrated circuit according to claim 1, wherein the automatic placement and routing block comprises:
a combinational logic circuit, comprising an input terminal group and an output terminal group;
a first scan D-type register group, coupled to the input terminal group of the combinational logic circuit; and
a second scan D-type register group, coupled between the output terminal group of the combinational logic circuit and the plurality of control signal output terminals of the automatic placement and routing block.

3. The integrated circuit according to claim 2, wherein, during a digital circuit test, the first scan D-type register group and the second scan D-type register group are configured in a digital test mode,
wherein, in the digital test mode, the first scan D-type register group and the second scan D-type register group are operated in a serial chain mode, a series of test signals is input to the first scan D-type register group via an external electronic design automation (EDA) tool, and test results are output from test pins electrically connected to the second scan D-type register group.

4. The integrated circuit according to claim 2, wherein the plurality of output terminals of the test pattern generation circuit are respectively coupled to the input terminals of the second scan D-type register group, and
during the analog test mode, the second scan D-type register group is configured in a normal mode, wherein a testing on whether a function of circuit between the output terminals of the second scan D-type register group and the control signal output terminals of the automatic placement and routing block is operated normally or not can be thereby performed.

5. The integrated circuit according to claim 1, wherein the test pattern generation circuit and the verification circuit are automatically generated by a hardware description language (HDL) based on a cell-based design flow.

6. The integrated circuit according to claim 1, wherein the check bit generation circuit is implemented by using a fully custom design flow.

7. The integrated circuit according to claim 1, wherein the check bit generation circuit comprises:
a plurality of exclusive-OR (XOR) logic gates, wherein each XOR logic gate comprises an input terminal respectively coupled to a test point within the analog circuit block; and
a check bit XOR logic gate, comprising a plurality of input terminals and an output terminal, wherein the plurality of input terminals of the check bit XOR logic gate are coupled to the output terminals of the XOR logic gates, and the output terminal of the check bit XOR logic gate outputs the check bit.

8. The integrated circuit according to claim 1, wherein the control interface block comprises:
a plurality of voltage level shifters, coupled between the control signal output terminals of the automatic placement and routing block and the control signal input terminals of the analog circuit block, for converting the voltage of the control signals from the second operating voltage to the first operating voltage.

9. The integrated circuit according to claim 1, wherein the test pattern generation circuit is implemented by using a polynomial operation.

10. The integrated circuit according to claim 1, wherein the test pattern generation circuit comprises:
a plurality of shift registers, wherein each shift register comprises an input terminal and an output terminal, wherein the output terminal of the K-th shift register is coupled to the input terminal of the (K+1)-th shift register, and a total number of the shift registers is determined by a highest degree of a polynomial operation; and
a plurality of chained feedback XOR operators, a number of the chained feedback XOR operators is determined by a number of terms in the polynomial operation, wherein for I-th term of degree J, an output terminal of the J-th shift register is coupled to an input terminal of the I-th feedback XOR operator, an output terminal of the first feedback XOR operator is coupled to an input terminal of the first shift register, and an input terminal of the first feedback XOR operator is coupled to an output terminal of the shift register corresponding to the smallest degree term,
wherein K is a natural number, K>0 and K<the highest polynomial degree,
wherein J is a natural number, J>0 and J≤the highest polynomial degree,
wherein I is a natural number, I>0 and I≤the number of terms in the polynomial.

11. A testing method for an integrated circuit, for testing the integrated circuit, the method comprising:
providing an analog circuit block and an automatic placement and routing block in the integrated circuit;
configuring a check bit generation circuit in the analog circuit block, wherein a plurality of test points in the analog circuit block is served as inputs of the check bit generation circuit for outputting a check bit;
configuring a test pattern generation circuit in the automatic placement and routing block for outputting a plurality of test signals via a plurality of control signal output terminals of the automatic placement and routing block;
when performing an analog circuit test, the method comprising:
activating the test pattern generation circuit to output the plurality of test signals;
generating a verification bit based on the test signals; and
verifying whether the check bit matches the verification bit;
determining a faulty of the integrated circuit when the check bit does not match the verification bit.

12. The testing method according to claim 11, wherein the automatic placement and routing block comprises:
a combinational logic circuit, comprising an input terminal group and an output terminal group;
a first scan D-type register group, coupled to the input terminal group; and
a second scan D-type register group, coupled between the output terminal group and the control signal output terminals of the automatic placement and routing block.

13. The testing method according to claim 12, wherein, during a digital circuit test, the method comprises:
configuring the first scan D-type register group and the second scan D-type register group in a digital test mode, where the first scan D-type register group and the second scan D-type register group operate in a serial chain mode; and
inputting a series of test signals into the first scan D-type register group via an external EDA tool, and outputting test results via test pins electrically connected to the second scan D-type register group.

14. The testing method according to claim 12, wherein the test pattern generation circuit and a verification circuit are automatically generated by a hardware description language based on a cell-based design flow, and a plurality of output terminals of the test pattern generation circuit are respectively coupled to the input terminals of the second scan D-type register group.

15. The testing method according to claim 14, during the analog test mode, further comprising:
configuring the second scan D-type register group in a normal mode;
wherein, during operation in the analog test mode, the test signals are used to verify an operation of circuit between the output terminals of the second scan D-type register group and the control signal output terminals of the automatic placement and routing block.

16. The testing method according to claim 11, wherein the check bit generation circuit comprises:
a plurality of XOR logic gates, comprising a plurality of input terminals which is respectively coupled to test points in the analog circuit block; and
a check bit XOR logic gate, comprising a plurality of input terminals and an output terminal, wherein the plurality of input terminals of the check bit XOR logic gate are coupled to the output terminals of the XOR logic gates, and the output terminal of the check bit XOR logic gate outputs the check bit.

17. The testing method according to claim 11, wherein a control interface block is provided between the analog circuit block and the automatic placement and routing block, coupled between the control signal output terminals of the automatic placement and routing block and a plurality of control signal input terminals of the analog circuit block, and wherein the control interface block comprises:
a plurality of voltage level shifters, coupled between the control signal output terminals of the automatic placement and routing block and the plurality of control signal input terminals of the analog circuit block, for converting voltages of the control signal from the second operating voltage to the first operating voltage.

18. The testing method according to claim 11, wherein the test pattern generation circuit is implemented by using a polynomial operation.

19. The testing method according to claim 11, wherein the test pattern generation circuit comprises:
a plurality of shift registers, wherein each shift register comprises an input terminal and an output terminal, wherein the output terminal of the K-th shift register is coupled to the input terminal of the (K+1)-th shift register, and a total number of the shift registers is determined by a highest degree of a polynomial operation; and
a plurality of chained feedback XOR operators, a number of the chained feedback XOR operators is determined by a number of terms in the polynomial operation, wherein for I-th term of degree J, an output terminal of the J-th shift register is coupled to an input terminal of the I-th feedback XOR operator, an output terminal of the first feedback XOR operator is coupled to an input terminal of the first shift register, and an input terminal of the first feedback XOR operator is coupled to an output terminal of the shift register corresponding to the smallest degree term,
wherein K is a natural number, K>0 and K<the highest polynomial degree,
wherein J is a natural number, J>0 and J≤the highest polynomial degree,
wherein I is a natural number, I>0 and I≤the number of terms in the polynomial.
